(19) United States
(12) Patent Application Publication
(10) Pub. No.: US 2007/0057333 A1
(43) Pub. Date: Mar. 15, 2007

(54) MOS transistor and method of manufacturing the same

(75) Inventors: Hong-Bae Park, Seoul (KR); Yu-Gyun Shin, Seongnam-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/519,063

(22) Filed: Sep. 12, 2006

(30) Foreign Application Priority Data
Sep. 13, 2005 (KR) 10-2005-0085148

(51) Int. Cl. H01L 29/94; H01L 21/336

(52) U.S. Cl. 257/411; 257/412; 438/585; 257/413; 438/261; 257/E29.128

(57) ABSTRACT

Example embodiments relate to a metal-oxide-semiconductor (MOS) transistor and a method of manufacturing the MOS transistor. In a MOS transistor and a method of manufacturing the same, a gate insulation layer may be formed on the channel region of the substrate, and may further include metal oxide or metal silicate. A buffer layer may be formed on the gate insulation layer. The buffer layer may further include any one selected from the group including silicon nitride, aluminum nitride, undoped polysilicon and combinations thereof. A gate conductive layer may be formed on the buffer layer and may further include polysilicon. The buffer layer may retard or prevent a reaction between the gate conductive layer and the gate insulation layer. Source/drain regions may be further formed at surface portions of the substrate and doped with impurities. A channel region may also be further formed at the surface portion of the substrate between the source/drain regions.

### PRIORITY STATEMENT

This application claims priority under 35 USC § 119 to Korean Patent Application No. 2005-85148, filed on Sep. 13, 2005, in the Korean Intellectual Property Office (KIPO), the entire contents of which are incorporated herein by reference.

### BACKGROUND

1. Field

Example embodiments relate to a metal-oxide-semiconductor (MOS) transistor and a method of manufacturing the MOS transistor. Other example embodiments relate to a MOS transistor including a gate insulation layer having metal oxide or metal silicate and a gate conductive layer having polysilicon, and a method of manufacturing the MOS transistor having the same.

2. Description of the Related Art

As semiconductor devices develop higher integrating degrees, a gate insulation layer of a recent metal-oxide-semiconductor (MOS) transistor may require lower equivalent oxide thickness (EOT) and sufficient reduction of current leakage between the gate conductive layer and a channel region. The gate insulation layer of the recent MOS transistor may include a material having a relatively high dielectric constant (hereinafter, referred to as high-k material), for example, a metal oxide. Examples of the metal oxide may include hafnium oxide, titanium oxide, zirconium oxide, aluminum oxide, tantalum oxide and/or any other suitable metal oxide.

The gate insulation layer including the metal oxide may have been formed by a chemical vapor deposition (CVD) process and/or an atomic layer deposition (ALD) process. When a gate insulation layer of a semiconductor device includes a metal oxide, current leakage may increase in the semiconductor device because the metal oxide may be crystallized at a relatively low temperature. Electrical reliability of the semiconductor device may be deteriorated. When the hafnium oxide layer is employed as the gate insulation layer, the gate insulation layer may be crystallized at a temperature above about 300° C. When a conductive layer includes polysilicon with impurities, the impurities, e.g., boron (B), may penetrate into the gate insulation layer, so that electron mobility in the channel region of the MOS transistor may decrease.

A metal silicate layer (e.g. the metal oxide layer containing silicon) may be employed as the gate insulation layer instead of the metal oxide layer. A metal silicate layer, containing nitride, may be used as the gate insulation layer in order to suppress a diffusion of the impurities (e.g., boron (B), phosphorus (P) and/or any other suitable impurity).

When a gate conductive layer, including polysilicon, is formed on the gate insulation layer, including metal oxide or metal silicate, the metal oxide or metal silicate in the gate insulation layer may react with polysilicon in the gate conductive layer so that a silicon oxide layer may be formed at an interface of the gate conductive layer and the gate insulation layer. The silicon oxide layer at the interface of the gate conductive layer and the gate insulation layer may generate a Fermi level pinning phenomenon, and mobility of the impurities in the gate conductive layer may be reduced to thereby reduce a threshold voltage (Vth). Because a flat band voltage (Vfb) is proportional to the threshold voltage (Vth), the flat band voltage (Vfb) may be more difficult to control due to the reduction of the threshold voltage.

A buffer layer, including a nitride (e.g., silicon nitride and/or aluminum nitride) and interposed between the gate insulation layer including metal oxide or metal silicate and the gate conductive layer including polysilicon, has been studied in the conventional art in order to address the issues above. For example, the conventional art discloses a method of forming a buffer layer between the gate insulation layer and the gate conductive layer.

When the buffer layer including silicon nitride or aluminum nitride is interposed between the gate insulation layer and the gate conductive layer, silicon nitride or aluminum nitride of the buffer layer may be reacted with polysilicon of the conductive layer to form a nitride layer at an interface of the buffer layer and the gate conductive layer. Resistance of the gate conductive layer may be augmented.

### SUMMARY

Example embodiments relate to a metal-oxide-semiconductor (MOS) transistor and a method of manufacturing the MOS transistor. Example embodiments provide MOS transistors and methods of manufacturing MOS transistors capable of retarding or preventing a reaction between a gate insulation layer and a gate conductive layer. According to example embodiments, a MOS transistor may include a gate insulation layer on a channel region of a semiconductor substrate, a buffer layer on the gate insulation layer, and a gate conductive layer on the buffer layer. The buffer layer may include any one selected from the group including silicon nitride, aluminum nitride, undoped polysilicon and combinations thereof. The buffer layer may retard or prevent a reaction between the gate conductive layer and the gate insulation layer. The MOS transistor may further include the semiconductor substrate, source and drain regions at surface portions of the substrate, the source and drain regions being doped with impurities and the channel region at the surface portion of the substrate between the source and drain regions. The gate insulation layer may include metal oxide and/or metal silicate and the gate conductive layer may include polysilicon.

In example embodiments, the buffer layer may include a stacked structure having a silicon nitride thin film and an undoped silicon thin film. The silicon nitride thin film may have a thickness of about 5 Å to about 50 Å and the undoped silicon thin film may have a thickness of about 10 Å to about 100 Å. The buffer layer may include a stacked structure having an aluminum nitride thin film and an undoped silicon thin film. The aluminum nitride thin film may have a thickness of about 5 Å to about 50 Å and the undoped silicon thin film may have a thickness of about 10 Å to about 100 Å.

According to example embodiments, there is provided a method of manufacturing a MOS transistor. A first thin layer may be formed on a semiconductor substrate by a chemical vapor deposition process, a sputtering process and/or an atomic layer deposition process and a second thin layer may be formed on the first thin layer. The second thin layer may include any one selected from the group including silicon nitride, aluminum nitride, undoped silicon and/or combinations thereof. A third thin layer may be formed on the second thin layer by a chemical vapor deposition process and the second thin layer may retard or prevent a reaction between the first thin layer and the third thin layer. The third, second and first thin layers may be patterned to thereby form a gate pattern including a gate conductive layer, a buffer layer and a gate insulation layer, respectfully. Source/drain regions may be formed at surface portions of the substrate adjacent to the gate pattern by implanting impurities onto the substrate using the gate pattern as an implantation mask. The first thin layer may include metal oxide or metal silicate. The third thin layer may include polysilicon.

In example embodiments, the second thin layer may include a silicon nitride thin film and may be formed on the first thin layer by a chemical vapor deposition process and/or an atomic layer deposition process, and an undoped silicon thin film may be formed in situ with the third thin layer. The silicon nitride thin film may be formed to a thickness of about 5 Å to about 50 Å and the undoped silicon thin film may be formed to a thickness of about 10 Å to about 100 Å.

In example embodiments, a thermal treatment and/or a plasma treatment may be further performed on the silicon nitride thin film after forming the silicon nitride thin film. The thermal treatment and/or the plasma treatment may be performed in an atmosphere of any one selected from the group including N₂, O₂, N₂O and NO.

In example embodiments, the second thin layer may include an aluminum nitride thin film formed on the first thin layer formed by a chemical vapor deposition process and/or an atomic layer deposition process, and an undoped silicon thin film may be formed in situ with the third thin layer. The aluminum nitride thin film may be formed to a thickness of about 5 Å to about 50 Å and the undoped silicon thin film may be formed to a thickness of about 10 Å to about 100 Å.

In example embodiments, a thermal treatment and/or a plasma treatment may be further performed on the aluminum nitride thin film after forming the aluminum nitride thin film. The thermal treatment or the plasma treatment may be performed in an atmosphere of any one selected from the group including N₂, O₂, N₂O and NO. According to example embodiments, a buffer layer, including one of silicon nitride and aluminum nitride, and undoped polysilicon, may be interposed between a gate insulation layer and a gate conductive layer and may retard or prevent a chemical reaction between the gate insulation layer and the conductive insulation layer to thereby improve the electrical characteristics of a MOS transistor.

### BRIEF DESCRIPTION OF THE DRAWINGS

Example embodiments will be more clearly understood from the following detailed description taken in conjunction with the accompanying drawings. FIGS. 1-3 represent non-limiting, example embodiments as described herein.

FIG. 1 is a diagram illustrating a MOS transistor in accordance with example embodiments;

FIGS. 2A to 2E are diagrams illustrating processing steps for a method of manufacturing the semiconductor MOS transistor shown in FIG. 1 in accordance with example embodiments; and

FIG. 3 is a graph illustrating capacitance-voltage curves of a MOS transistor in accordance with example embodiments.

### DETAILED DESCRIPTION OF EXAMPLE EMBODIMENTS

Example embodiments are described more fully hereinafter with reference to the accompanying drawings, in which example embodiments are shown. The example embodiments may, however, be embodied in many different forms and should not be construed as limited to the embodiments set forth herein. Rather, these example embodiments are provided so that this disclosure will be thorough and complete, and will fully convey the scope of example embodiments to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to limit example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-section illustrations that are schematic illustrations of idealized embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Example embodiments relate to a metal-oxide-semiconductor (MOS) transistor and a method of manufacturing the MOS transistor.

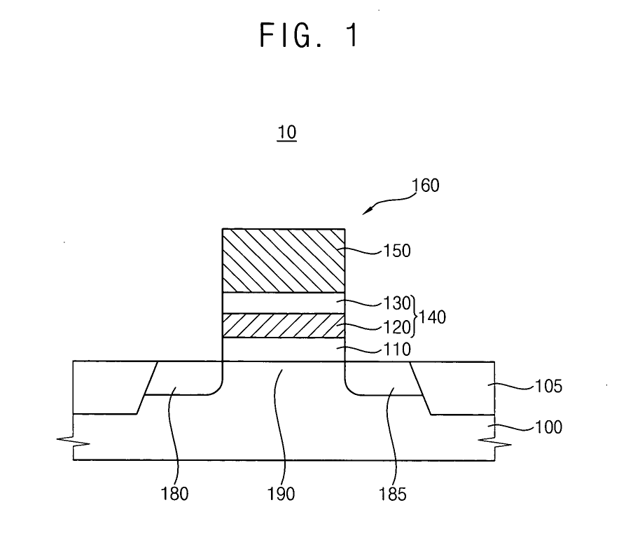

FIG. 1 is a diagram illustrating a MOS transistor in accordance with example embodiments. Referring to FIG. 1, a metal-oxide-semiconductor (MOS) transistor 10 in accordance with example embodiments may include a gate pattern 110 formed on a semiconductor substrate 100, source and drain regions 180 and 185 and a channel region 190.

The semiconductor substrate 100 may include a silicon substrate, a silicon-on-insulator (SOI) substrate, a germanium substrate, a germanium on insulator (GOI) substrate, a silicon-germanium substrate, an epitaxial thin layer formed by a selective epitaxial growth process and/or any other suitable material. In example embodiments, the semiconductor substrate 100 may include the silicon substrate. In other example embodiments, when the MOS transistor 10 includes a plurality of layers vertically stacked on the substrate 100, the substrate 100 may include the epitaxial thin layer that is formed by the selective epitaxial growth process.

The MOS transistor 10 may further include a well (not shown) and an isolation layer 105. When the MOS transistor 10 includes an N type MOS transistor, the semiconductor substrate 100 may include a P type well (not shown) doped with a relatively low concentration of P type impurities, e.g., boron (B). When the MOS transistor 100 includes a P type MOS transistor, the semiconductor substrate 100 may include an N type well (not shown) doped with a relatively low concentration of N type impurities (e.g., phosphorus (P), arsenic (As) and/or any other suitable N type impurities).

The isolation layer 105 may be formed at an upper portion of the semiconductor substrate 100. The isolation layer 105 may divide the semiconductor substrate 100 into an active region and a field region. The isolation layer 105 may include a field oxide layer, a trench isolation layer and/or any other suitable layer. In example embodiments, the isolation layer 105 may include the trench isolation layer because the trench isolation layer may have an improved degree of integration as compared with the field oxide layer.

The source and drain regions 180 and 185, doped with impurities, may be formed at surface portions of the semiconductor substrate 100. The source and drain regions 180 and 185 may be formed at the surface portions of the substrate 100 adjacent to a gate pattern 160 on the substrate 100. The impurities may be doped into the source and drain regions 180 and 185 by an ion implantation process. When the MOS transistor 10 is an N type transistor, free electrons may be used as carriers in operating the transistor. The source/drain regions 180 and 185 of the N type transistor may be doped with N type impurities (e.g., phosphorus (P), arsenic (As) and/or any other suitable N type impurities), because the N type impurities may generate a plurality of free electrons. When the MOS transistor 10 is a P type transistor, holes may be used as carriers in operating the transistor. The source/drain regions 180 and 185 of the P type transistor may be doped with P type impurities (e.g., boron (B) and/or gallium (Ga)), because the P type impurities may generate a plurality of holes.

The channel region 190 may be positioned below the surface of the semiconductor substrate 100 between the source/drain regions 180 and 185. The gate pattern 160 may be formed on the channel region 190 of the semiconductor substrate 100. The gate pattern 160 may include a gate insulation layer 110, a buffer layer 140 and a gate conductive layer 150.

The gate insulation layer 110 may be interposed between the channel region 190 and the gate conductive layer 150. The gate insulation layer 110 may electrically isolate the gate conductive layer 150 from the channel region 190 without current leakage. The gate insulation layer 110 may include a metal oxide or a metal silicate, so that an EOT of the gate insulation layer may be smaller and a current leakage may be reduced. For example, the metal oxide may include hafnium oxide, zirconium oxide, tantalum oxide, aluminum oxide, titanium oxide and/or any other suitable metal oxide. These can be used alone or in combinations thereof. The metal silicate may include hafnium silicon oxide, zirconium silicon oxide, tantalum silicon oxide, aluminum silicon oxide, titanium silicon oxide and/or any other suitable material. These can be used alone or in combinations thereof.

The gate insulation layer 110 including the metal oxide or the metal silicate may be formed by a chemical vapor deposition (CVD) process, a sputtering process and/or an atomic layer deposition (ALD) process. In example embodiments, the gate insulation layer 110 may be formed by the ALD process because an integration degree may be improved when formed by the ALD process. The gate insulation layer 110 may have an EOT of about 20 Å. The buffer layer 140 may be interposed between the gate insulation layer 110 and the gate conductive layer 150. The buffer layer 140 may retard or prevent the gate insulation layer 110 and the gate conductive layer 150 from reacting with each other. When the gate insulation layer 110 includes the metal oxide or the metal silicate and the gate conductive layer 150 includes polysilicon, the buffer layer 140 may retard or prevent the gate insulation layer 110 and the gate conductive layer 150 from reacting with each other.

For example, the buffer layer 140 may include silicon nitride, aluminum nitride or pure silicon without any impurities, so that metal nitride or metal silicate of the gate insulation layer 110 may be retarded or prevented from reacting with polysilicon of the gate conductive layer 25. In example embodiments, the buffer layer 140 may have a dual layer structure including a first thin film 120 and a second thin film 130 that are sequentially stacked on the gate insulation layer 110. The first thin film 120 may include a silicon nitride thin film or an aluminum nitride thin film; whereas the second thin film 130 may include an undoped polysilicon thin film. For example, the buffer layer 140 may include the silicon nitride thin film and the undoped polysilicon thin film stacked on the silicon nitride thin film, or may include the aluminum nitride thin film and the undoped polysilicon thin film stacked on the aluminum nitride thin film.

The first thin film 120 may be formed on the gate insulation layer by a CVD process and/or an ALD process because the first thin film 120 may include silicon nitride or aluminum nitride. In example embodiments, the first thin film 120 may be formed through the ALD process because a degree of integration may be improved when the ALD process is used. The second thin film 130 may be formed on the first thin film 120 in situ with the gate conductive layer 150 in a subsequent process because the second thin film may include undoped polysilicon. The first thin film 120 may be formed to a thickness of about 5 Å to about 50 Å and the second thin film 130 may be formed to a thickness of about 10 Å to about 100 Å. The gate conductive layer 150 may be formed on the buffer layer 140. The gate conductive layer 150 may include polysilicon having lower electrical resistance and improved stability, so that the gate conductive layer 150 may have improved electrical performance and oxidation resistance and improved stiffness when absorbing an exterior mechanical stress.

In example embodiments, the gate conductive layer 150 may be formed by a CVD process. The gate conductive layer 150 may be formed on the first thin film 120 to a thickness of about 800 Å to about 1,500 Å through a low pressure chemical vapor deposition (LPCVD) process using a thermal dissociation of silane (SiH₄) gas. According to example embodiments, the MOS transistor 10 may include a gate pattern having the gate insulation layer 110, the buffer layer 140 and the gate conductive layer 150 that may be sequentially stacked on the channel region 190 of the substrate. The gate insulation layer may include metal oxide or metal silicate and may be formed on the channel region 190 of the semiconductor substrate 100. The buffer layer 140 may include the first thin film including one of silicon nitride and aluminum nitride and a second thin film including undoped polysilicon, and may be formed on the gate insulation layer 110. The gate conductive layer 150 may include undoped polysilicon and may be formed on the buffer layer 140.

The gate insulation layer 110 of the MOS transistor 100 may have a relatively small EOT and reduced current leakage, and the gate conductive layer 150 may have improved stability and an increase of integration degree of the MOS transistor. The MOS transistor 100 may have improved electric characteristics and the degree of integration thereof may be more easily increased.

The buffer layer 140 may include one of silicon nitride and aluminum nitride, and undoped polysilicon, so that the chemical reaction between the gate conductive layer 150 and the gate insulation layer 110 may be retarded or prevented in the MOS transistor. The MOS transistor may be less influenced by a Fermi level pinning effect and may have improved electrical characteristics.

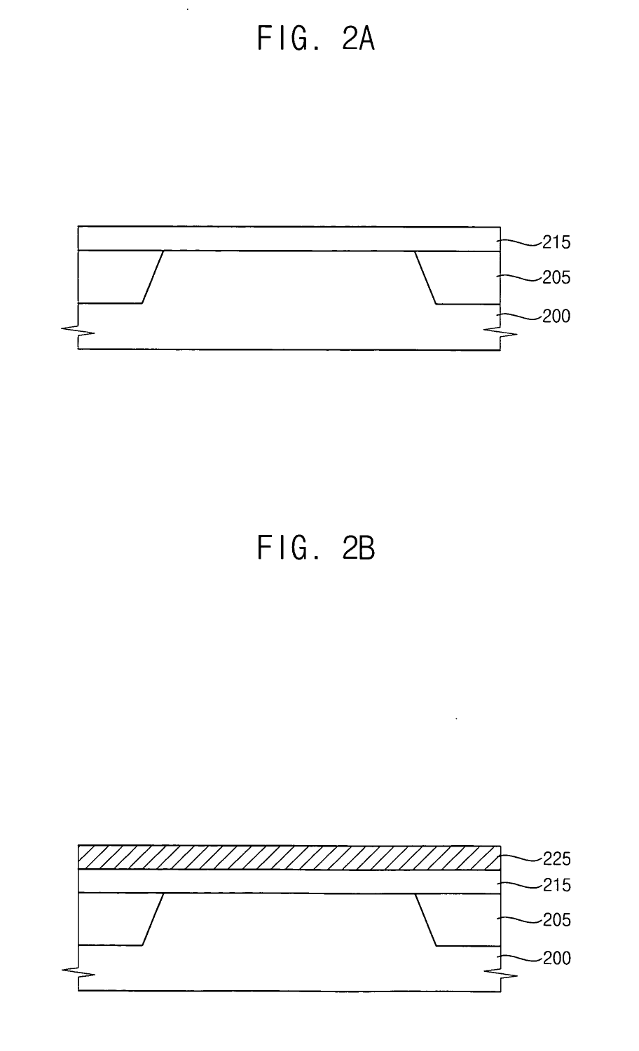

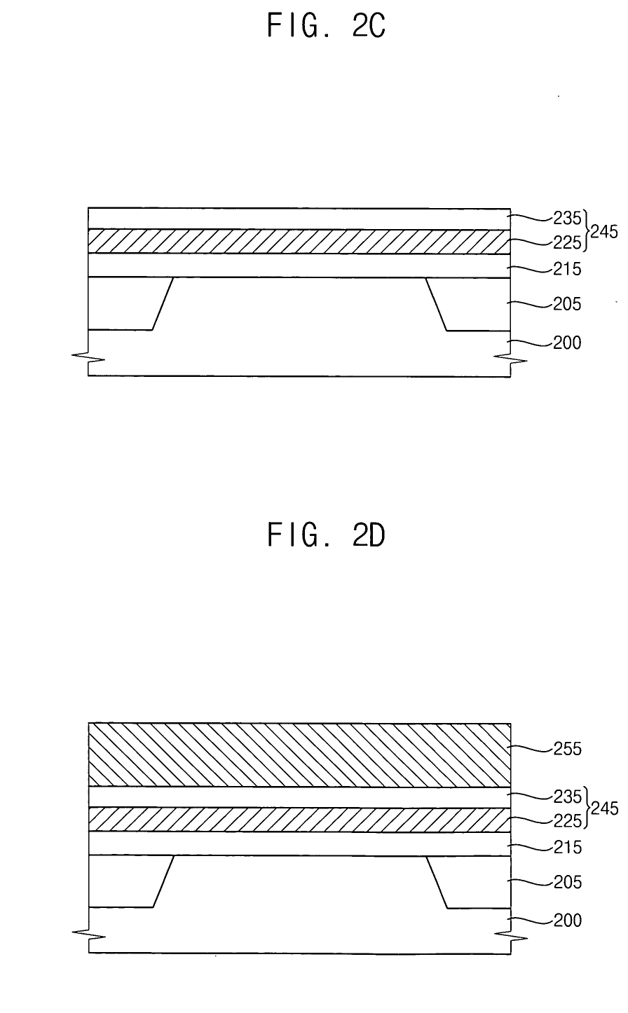

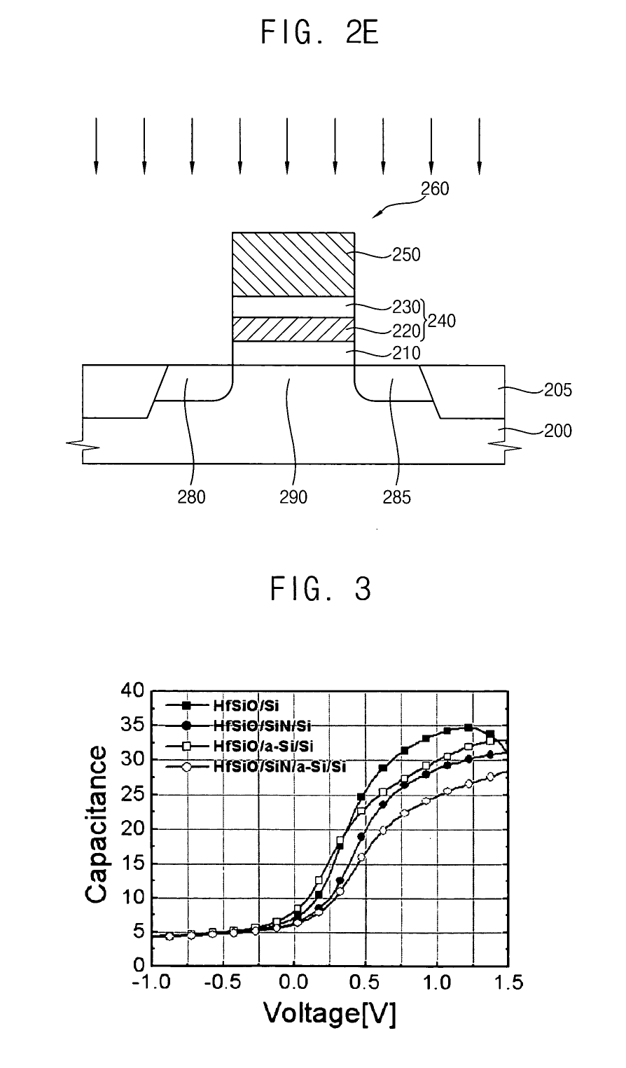

FIGS. 2A to 2E are diagrams illustrating processing steps for a method of manufacturing the semiconductor MOS transistor illustrated in FIG. 1 according to example embodiments. Referring to FIG. 2A, an isolation layer 205 may be formed on an upper portion of a semiconductor substrate 200. The isolation layer 205 may divide the semiconductor substrate 200 into an active region and a field region. The isolation layer 205 may be formed by a shallow trench isolation (STI) process and/or a local oxidation of silicon (LOCOS) process. In example embodiments, the isolation layer 205 may be formed by the STI process because the STI process provides an increase of an integration degree of a transistor as compared with the LOCOS process.

A pad oxide layer (not shown) and a pad nitride layer (not shown) may be sequentially formed on the semiconductor substrate 200, and then, may be patterned to thereby form a pad oxide layer pattern (not shown) and a pad nitride layer pattern (not shown) on the substrate 200. The substrate 200 may then be partially exposed through the pad oxide layer pattern and the pad nitride layer pattern. An etching process may be performed on the substrate using the pad oxide layer pattern and the pad nitride layer pattern as etching masks to thereby form a trench on the substrate 100. A curing process may be further performed on the substrate 200 including the trench, so that damage to the substrate 200 in the above etching process may be repaired. An oxide layer (not shown), having improved gap-filling characteristics, may be then formed on the substrate 200, including the trench, to a sufficient thickness to fill up the trench by, for example, a plasma-enhanced chemical vapor deposition (PECVD) process. The oxide layer may be removed by a planarization process until a top surface of the pad nitride layer pattern is exposed, so that the trench may be filled with the oxide layer. The planarization process may include a chemical mechanical polishing (CMP) process. The pad nitride layer pattern and the pad oxide layer pattern may be removed from the semiconductor substrate 200 by, for example, an etching process using an etchant including phosphoric acid. The oxide layer may remain in the trench of the substrate 200 to thereby form the isolation layer 205 on the substrate 200. The isolation layer 205 may be referred to as a trench isolation layer because the isolation layer may be formed by a STI process.

A first thin layer 215 may be formed on the semiconductor substrate 200 including the trench isolation layer 205. The first thin layer 215 may be patterned into the gate insulation layer of the gate pattern. The first thin layer 215 may include a metal oxide layer or a metal silicate layer, and may be formed to an EOT less than or equal to about 20 Å. The first thin layer 215 may be formed by a CVD process, a sputtering process, an ALD process and/or any other suitable process. In example embodiments, the first thin layer 215 may be formed by the ALD process to a higher integration degree.

Hereinafter, an ALD process for forming the first thin layer 215 may be described in detail. First reactants, including metal precursors, may be introduced onto the semiconductor substrate 200 in a chamber where a temperature is in a range of about 200° C. to about 500° C. and a pressure is in a range of about 0.3 torr to about 3.0 torr. The first reactants may be introduced into the chamber for about 0.5 seconds to about 3 seconds. A first portion of the first reactants may be chemically absorbed (e.g., chemisorbed) onto the substrate 200 and a second portion of the first reactants may be physically absorbed (e.g. physisorbed) onto the first portion of the first reactants or drift in the chamber.

A first purge gas, e.g., argon (Ar) gas, may be introduced into the chamber for about 0.5 seconds to about 20 seconds. The second portion of the first reactants physisorbed onto the first portion, or adrift in the chamber, may be removed from the chamber through a first purge process. The first portion of the reactants may be chemisorbed onto the substrate 200. The first portion of the first reactants, which are molecules of the metal precursors, may remain on the substrate 200.

An oxidant may be introduced into the chamber for about 1 second to about 7 seconds, so that the metal precursors chemisorbed onto the semiconductor substrate 200 may be chemically reacted with an oxidant. The metal precursors may be oxidized by the oxidant. A second purge gas may be introduced into the chamber. Residuals of the oxidant, which are not reacted with the metal precursors, may be removed from the chamber through a second purge process. A solid material, including metal oxide, may be deposited on the semiconductor substrate 200. In example embodiments, the second purge gas may be substantially the same as the first purge gas.

The above steps of introducing the reactant, the first purge gas, the oxidant and the second purge gas may be repeated at least once, so that the first thin layer 215 may be formed on the semiconductor substrate 200. In example embodiments, the first thin layer 215 may be formed on the semiconductor substrate 200 as illustrated above. In example embodiments, a thin layer (not shown), including silicon oxide, may be further formed on the semiconductor substrate 200 and then the first thin layer 215 may be formed on the thin layer. The thin layer, interposed between the first thin layer 215 and the substrate 200, may improve boundary characteristics of the first thin layer 215 with respect to the substrate 200.

Referring to FIG. 2B, a first sub-layer 225 may be formed on the first thin layer 215. The first sub-layer 225 may be formed using silicon nitride or aluminum nitride. The first sub-layer 225, which may include silicon nitride or aluminum nitride, may be formed to a thickness of about 5 Å to about 50 Å by a CVD process and/or an ALD process. In example embodiments, the first sub-layer 225, including silicon nitride, may be formed by the CVD process, whereas the first sub-layer 225 including aluminum nitride may be formed by the ALD process.

In forming the first sub-layer 225, including silicon nitride, by the CVD process, silane (SiH₄) gas may be reacted with ammonia (NH₃) gas in a processing chamber at a temperature of about 700° C. to about 900° C. and under an atmospheric pressure. Dichlorosilane (SiCl₂H₂) gas may be reacted with ammonia (NH₃) gas in a processing chamber at a temperature of about 700° C. to about 800° C. and under an atmospheric pressure. The ALD process for forming the first sub-layer 225, including aluminum nitride, may be performed as follows.

The semiconductor substrate 200, including the first thin layer 215, may be loaded into a chamber. In example embodiments, the chamber may be maintained at a temperature of about 400° C. and under a pressure of about 1 torr. When the temperature in the chamber is undesirably low, reactivity of the reactants may be reduced and the deposition rate of the first sub-layer 225 may be negligible, which reduces productivity. When the temperature in the chamber is undesirably high, the ALD process may be performed just like a CVD process. Second reactants, including aluminum precursors, may be introduced onto the first thin layer 215 on the substrate 200 for about 0.3 seconds to about 1.0 second. For example, the second reactants may include trimethyl aluminum (Al(CH₃)₃; TMA) as the aluminum precursor. As described above, a first portion of the second reactants, including the aluminum precursors, may be chemisorbed onto the first thin layer 215, and a second portion of the second reactants may be physisorbed onto the first portion of the second reactants or drifts in the chamber. The molecules of the aluminum precursors may be chemisorbed onto the first thin layer 215.

A third purge gas (e.g., nitrogen (N₂) gas) may be introduced into the chamber for about 0.5 seconds to about 5 seconds, so that the second portion of the second reactants physisorbed onto the first portion or adrift in the chamber may be removed from the chamber through a third purge process. The first portion of the second reactants may be chemisorbed onto the first thin layer 215. The first portion of the second reactants, which are molecules of the aluminum precursors, may remain on the first thin layer 215.

A nitrogen reactant (e.g., ammonia gas) may be introduced into the chamber for about 0.3 seconds to about 1.0 second, so that the nitrogen reactant may be chemically reacted with the molecules of the aluminum precursor which are chemisorbed onto the first thin layer 215. The aluminum precursors may be nitrified by nitrogen. A fourth purge gas (e.g., nitrogen gas) may be introduced into the chamber, and residuals of the nitrogen reactants, which are not reacted with the aluminum precursors, may be removed from the chamber through a fourth purge process. A solid material, including aluminum nitride, may be deposited on the first thin layer 215.

The above steps of introducing the second reactants including aluminum precursors, the third purge gas, the nitrogen reactants and the fourth purge gas may be repeated at given times, so that the first sub-layer 225, including aluminum nitride, may be formed on the first thin layer 215 to a desired thickness. In example embodiments, after the first sub-layer 225, including silicon nitride or aluminum nitrides, is formed on the first thin layer 215, a post treatment may be further performed on the semiconductor substrate 200 to thereby improve layer characteristics of the first sub-layer 225. For example, a heat treatment and/or a plasma treatment may be carried out in an atmosphere of N₂, O₂, N₂O and NO as the post treatment.

Referring to FIG. 2C, a second sub-layer 235, including undoped polysilicon, may be formed on the first sub-layer 225, including silicon nitride or aluminum nitride, to a thickness of about 10 Å to about 100 Å. A second thin layer 245, including the first and the second sub-layers 225 and 235, may be formed on the first thin layer 215. In example embodiments, the second sub-layer 235, including undoped polysilicon, may be formed by an epitaxial growth process and/or a CVD process using silane gas and/or dichlorosilane gas as a reaction gas.

Referring to FIG. 2D, a third thin layer 255 may be formed on the second sub-layer 235 including undoped polysilicon. The third thin layer 255 may be patterned into a gate conductive layer 250 (see FIG. 2E) of a gate pattern 260 in a subsequent process. The third thin layer 255 may be formed using polysilicon. In example embodiments, the third thin layer 255 may be formed through a thermal decomposition process using silane gas, which is similar to a CVD process, to a thickness of about 800 Å to about 1,500 Å. The thermal decomposition process, using the silane gas, may include a first step of forming a layer on the second sub-layer 235 and a second step of implanting impurities onto the layer. The thermal decomposition process may be carried out at a temperature of about 500° C. to about 650° C. and under a pressure of about 25 Pa to about 150 Pa. In example embodiments, the third thin layer 255 may be formed in-situ with the second sub-layer 235, because the third thin layer 235 and the second sub-layer 235 may be formed under similar processing conditions using the same reactants.

Referring to FIG. 2E, the third thin layer 255, the second thin layer 245 including the first and the second sub-layers 225 and 235 and the first thin layer 215 may be sequentially patterned by a photolithographic process using a photoresist pattern as an etching mask in order to form a gate insulation layer 210, a buffer layer 240 including a first sub-pattern 220 and a second sub-pattern 230 and a gate conductive layer 250. A gate pattern 260 including the gate insulation layer 210, the buffer layer 240 and the gate conductive layer 250 may be formed on the semiconductor substrate 200.

An ion implantation process may be further carried out on the semiconductor substrate 200 using the gate pattern 260 as an implantation mask, so that impurities may be implanted onto the semiconductor substrate 200 adjacent to the gate pattern 260. When a polarity of the impurities are N type (e.g., phosphorus (P), arsenic (As) and/or any other suitable N type impurities), the MOS transistor 10 in FIG. 1 may be formed into an N type transistor. When a polarity of the impurities are P type (e.g., gallium (Ga), indium (In) and/or any other suitable P type impurities), the MOS transistor in FIG. 1 may be formed into a P-type transistor. Source and drain regions 280 and 285, including doped impurities, may be formed at surface portions of the semiconductor substrate 200 adjacent to the gate pattern 260. A channel region 290 may be formed on the substrate between the source and the drain regions 280 and 285.

In example embodiments, a spacer (not shown) may be further formed at a sidewall of the gate pattern 260. Particularly, a silicon nitride layer is continuously formed on the gate pattern 260 and the semiconductor substrate 200, and then the silicon nitride layer is anisotropically etched off from the substrate 200 to form a spacer on the sidewall of the gate pattern 260. When the spacer is formed on the sidewall of the gate pattern 260, an ion implantation process may be further carried out on the semiconductor substrate 200 using the gate pattern 260 and the spacer as implantation masks. The source and drain regions (not shown) may be formed into a lightly doped source/drain (LDD) structures including a shallow junction region and a deep junction region.

Evaluation of Capacitance-Voltage Characteristics

FIG. 3 is a graph illustrating capacitance-voltage curves of a MOS transistor in accordance with example embodiments. In FIG. 3, a symbol ‘▪’ denotes a capacitance with respect to a voltage applied to a MOS transistor in which a gate insulation layer may include hafnium silicate and a gate conductive layer may include polysilicon. A symbol ‘●’ denotes a capacitance with respect to a voltage applied to a MOS transistor in which a gate insulation layer may include hafnium silicate, a buffer layer may include silicon nitride and a gate conductive layer may include polysilicon. A symbol ‘□’ denotes a capacitance with respect to a voltage applied to a MOS transistor in which a gate insulation layer may include hafnium silicate, a buffer layer may include undoped polysilicon and a gate conductive layer may include polysilicon. A symbol ‘∘’ denotes a capacitance with respect to a voltage applied to a MOS transistor in which a gate insulation layer may include hafnium silicate, a buffer layer may include silicon nitride and undoped polysilicon, and a gate conductive layer may include polysilicon.

FIG. 3 shows that the capacitance-voltage curve represented by a plurality of the symbols ‘∘’ has the most improved flat band voltage. The MOS transistor may have the most improved operation characteristics when the gate insulation layer may include hafnium silicate, the buffer layer may include silicon nitride and undoped polysilicon, and the gate conductive layer may include polysilicon.

According to example embodiments, a buffer layer, including one of silicon nitride and aluminum nitride, and undoped polysilicon, may be interposed between a gate insulation layer and a gate conductive layer and may improve electrical characteristics of a MOS transistor. The gate insulation layer, including metal oxide or metal silicate, may produce an increase in an integration degree of the MOS transistor and the conductive layer, including polysilicon, may enable the MOS transistor to have improved electrical characteristics and stability.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of example embodiments. All such modifications are intended to be included within the scope as defined in the claims. In the claims, means-plus-function clauses are intended to cover the structures described herein as performing the recited function and not only structural equivalents but also equivalent structures. Therefore, it is to be understood that the foregoing is illustrative and is not to be construed as limited to the specific embodiments disclosed, and that modifications to the disclosed embodiments, as well as other example embodiments, are intended to be included within the scope of the appended claims. Example embodiments are defined by the following claims, with equivalents of the claims to be included therein.

What is claimed is:

1. A MOS transistor comprising:
a gate insulation layer on a channel region of a semiconductor substrate;
a buffer layer on the gate insulation layer, the buffer layer including any one selected from the group consisting of silicon nitride, aluminum nitride, undoped polysilicon and combinations thereof; and
a gate conductive layer that is formed on the buffer layer, wherein the buffer layer retards a reaction between the gate conductive layer and the gate insulation layer.

2. The MOS transistor of claim 1, further comprising:
the semiconductor substrate;
source and drain regions at surface portions of the substrate, the source and drain regions being doped with impurities; and
the channel region at the surface portion of the substrate between the source and drain regions.

3. The MOS transistor of claim 1, wherein the gate insulation layer includes metal oxide or metal silicate.

4. The MOS transistor of claim 1, wherein the gate conductive layer includes polysilicon.

5. The MOS transistor of claim 1, wherein the buffer layer includes a stacked structure having a silicon nitride thin film and an undoped silicon thin film.

6. The MOS transistor of claim 5, wherein the silicon nitride thin film has a thickness of about 5 Å to about 50 Å and the undoped silicon thin film has a thickness of about 10 Å to about 100 Å.

7. The MOS transistor of claim 1, wherein the buffer layer includes a stacked structure having an aluminum nitride thin film and an undoped silicon thin film.

8. The MOS transistor of claim 7, wherein the aluminum nitride thin film has a thickness of about 5 Å to about 50 Å and the undoped silicon thin film has a thickness of about 10 Å to about 100 Å.

9. A method of manufacturing a MOS transistor, comprising:
forming a first thin layer on a semiconductor substrate;
forming a second thin layer on the first thin layer, the second thin layer including any one selected from the group consisting of silicon nitride, aluminum nitride, undoped silicon and combinations thereof;
forming a third thin layer on the second thin layer, wherein the second thin layer retards a reaction between the first thin layer and the third thin layer; and
patterning the third, second and first thin layers to thereby form a gate pattern including a gate conductive layer, a buffer layer, and a gate insulation layer, respectively.

10. The method of claim 9, further comprising:
forming source/drain regions at surface portions of the substrate adjacent to the gate pattern by implanting impurities onto the substrate using the gate pattern as an implantation mask.

11. The method of claim 9, wherein the first thin layer includes metal oxide or metal silicate.

12. The method of claim 9, wherein the third thin layer includes polysilicon.

13. The method of claim 9, wherein forming the second thin layer includes:
forming a silicon nitride thin film on the first thin layer by a chemical vapor deposition process or an atomic layer deposition process; and
forming an undoped silicon thin film in-situ with the third thin layer.

14. The method of claim 13, wherein the silicon nitride thin film is formed to a thickness of about 5 Å to about 50 Å and the undoped silicon thin film is formed to a thickness of about 10 Å to about 100 Å.

15. The method of claim 13, wherein a thermal treatment or a plasma treatment is further performed on the silicon nitride thin film after forming the silicon nitride thin film.

16. The method of claim 15, wherein the thermal treatment and the plasma treatment is performed at an atmosphere of any one selected from the group including N₂, O₂, N₂O and NO.

17. The method of claim 9, wherein forming the second thin layer includes:
forming an aluminum nitride thin film on the first thin layer by a chemical vapor deposition process or an atomic layer deposition process; and
forming an undoped silicon thin film in situ with the third thin layer.

18. The method of claim 17, wherein the aluminum nitride thin film is formed to a thickness of about 5 Å to about 50 Å and the undoped silicon thin film has a thickness of about 10 Å to about 100 Å.

19. The method of claim 17, wherein a thermal treatment or a plasma treatment is further performed on the aluminum nitride thin film after forming the aluminum nitride thin film.

20. The method of claim 19, wherein the thermal treatment and the plasma treatment is performed at an atmosphere of any one selected from the group including N₂, O₂, N₂O and NO.
